(19) United States
(12) Patent Application Publication
(10) Pub. No.: US 2017/0132995 A1
(43) Pub. Date: May 11, 2017

(54) Portable Amplification Unit

(71) Applicant: Markus Oliver Hummel, Los Altos Hills, CA (US)

(72) Inventor: Markus Oliver Hummel, Los Altos Hills, CA (US)

(21) Appl. No.: 15/410,601

(22) Filed: Jan. 19, 2017

Related U.S. Application Data
(63) Continuation-in-part of application No. 15/134,777, filed on Apr. 21, 2016, now Pat. No. 9,583,085.
Application No. 15/134,777 is a continuation of application No. 14/629,692, filed on Feb. 24, 2015, now Pat. No. 9,349,360.
Application No. 14/629,692 is a continuation-in-part of application No. 14/073,689, filed on Nov. 6, 2013, now Pat. No. 9,012,759.
Application No. 15/134,777 is a continuation-in-part of application No. 15/045,637, filed on Feb. 17, 2016, now Pat. No. 9,373,315.
Application No. 15/045,637 is a continuation-in-part of application No. 14/632,521, filed on Feb. 26, 2015, now Pat. No. 9,293,125.
Application No. 14/632,521 is a continuation of application No. 14/073,689, filed on Nov. 6, 2013, now Pat. No. 9,012,759.
Application No. 14/073,689 is a continuation-in-part of application No. 61/724,106, filed on Nov. 8, 2012.
(60) Provisional application No. 62/280,482, filed on Jan. 19, 2016.
(60) Provisional application No. 61/946,450, filed on Feb. 28, 2014.
(60) Provisional application No. 61/948,448, filed on Mar. 5, 2014.
(60) Provisional application No. 61/724,106, filed on Nov. 8, 2012.

(51) Int. Cl. G10H 3/18; H03F 3/181; G10D 1/08; G10H 1/46; H04R 1/02

(52) U.S. Cl. CPC G10H 3/186; G10H 1/46; H04R 1/025; G10D 1/085; H03F 3/181; H04R 2201/028; H03F 2200/03

(57) ABSTRACT

A portable amplification unit that is integrated directly into the body of an electric instrument, thus eliminating external cables and devices. The portable amplification unit includes an amplifier cartridge that houses an amplification assembly. The amplification cartridge is attached to, and electrically connected to, an instrument through a cartridge receiver. A pre-amplifier assembly of the amplification assembly provides a first stage of amplification, while a power amplifier circuit provides a second stage of amplification. A power supply provides current to amplify the electrical signal of the instrument. A pre-amp control and a master volume control allow for adjusting the magnitude of amplification. A speaker is also integrated into the amplifier cartridge; the speaker being electrically connected to the power amplifier circuit.

The current application claims benefit to U.S. Provisional Patent Application Ser. No. 62/280,482 filed on Jan. 19, 2016.

The current application is further a continuation in part of U.S. Utility patent application Ser. No. 15/134,777 filed on Apr. 21, 2016 which is a continuation of U.S. Utility application Ser. No. 14/629,692 filed on Feb. 24, 2015 which claims benefit to U.S. Provisional Patent Application Ser. No. 61/946,450 filed on Feb. 28, 2014, claims benefit to U.S. Provisional Patent Application Ser. No. 61/948,448 filed on Mar. 5, 2014, and is a continuation in part of U.S. Utility patent application Ser. No. 14/073,689 filed on Nov. 6, 2013 which claims benefit of U.S. Provisional Patent Application Ser. No. 61/724,106 filed on Nov. 8, 2012.

U.S. Utility patent application Ser. No. 15/134,777 filed on Apr. 21, 2016 is a continuation in part of U.S. Utility patent application Ser. No. 15/045,637 filed on Feb. 17, 2016 which is a continuation in part of U.S. Utility patent application Ser. No. 14/632,521 filed on Feb. 26, 2015 which is a continuation of U.S. Utility patent application Ser. No. 14/073,689 filed on Nov. 6, 2013 which claims benefit to U.S. Provisional Patent Application Ser. No. 61/724,106 filed on Nov. 8, 2012.

### FIELD OF THE INVENTION

The present invention relates generally to instrument amplification. More specifically, the present invention is a portable amplification unit that is integrated directly into the body of an electric instrument.

### BACKGROUND OF THE INVENTION

An electric guitar utilizes a pickup to convert the vibration of the strings into electrical impulses. However, the electrical signals produced are very weak and cannot be used to drive a speaker on their own. As such, amplifiers are used to boost the electrical signals, wherein the amplified signals are strong enough to drive a speaker. One issue with the use of amplifiers with electric guitars is cable signal loss, which is due, at least in part, to the length of the guitar cable that is used between the guitar and the amplifier. The cable signal loss across the guitar cable between where the electronic signal of the guitar is generated to where the signal is amplified results in a loss in tone, which is undesirable to most musicians. Ideally, the electrical signals are amplified as close to the signal generation as possible in order to reduce the amount of signal loss that occurs. However, the use of a shorter guitar cable between the guitar and the amplifier restricts the movements of the user as they play the instrument. Another issue associated with amplifiers is their size and portability. Amplifiers are typically large and bulky and thus can be quite difficult to carry while traveling. Additionally, large amplifiers are not as well suited for simply practicing or playing in confined spaces.

Therefore it is an object of the present invention to provide a portable amplification unit that is integrated into the body of an electric instrument for easy access and manipulation of controls and reduction in signal loss. A cartridge receiver is integrated into the body of the instrument, while an amplifier cartridge housing an amplification assembly is attached to the instrument via the cartridge receiver. Signal loss between signal generation and the amplification of the signal is reduced or altogether eliminated as the cartridge receiver is mounted directly onto the electric instrument, thus reducing the length of wire that the generated electrical signal must traverse in order to reach the amplification assembly. Together, the cartridge receiver and the amplifier cartridge provide electronic connections between the electric instrument and the amplification assembly. The amplification assembly includes a pre-amplifier circuit and a power amplifier circuit for amplifying the electronic signal of the electric instrument, as well as an at least one amplifier control for adjusting the extent to which the amplitude of the electronic signal is increased. The at least one amplifier control is connected to the amplification cartridge, such that the at least one amplifier control is within a hand's reach while the electric instrument is being played, thus giving the musician much greater control over the sound of his or her electric instrument.

### BRIEF DESCRIPTION OF THE DRAWINGS

FIG. 1 is a front view of the portably amplification unit being integrated into an electric guitar.

FIG. 2 is a perspective view of the portable amplification unit detailing the signal-in port positioned about the top of the cartridge casing, the at least one amplifier control connected to the cartridge casing, and the speaker positioned within the cartridge casing.

FIG. 3 is a front elevational view thereof.

FIG. 4 is a right side elevational view detailing the at least one amplifier control being a master volume control, a pre-amp control, and a channel switch.

FIG. 5 is left side elevational view detailing the output port and the input port.

FIG. 6 is a rear sectional view showing the power amplifier circuit, the pre-amplifier circuit, and the power source positioned within the cartridge casing.

FIG. 7 is a perspective view of the cartridge receiver showing a receiving volume for accepting the amplifier cartridge.

FIG. 8 is a front sectional view of the amplifier cartridge positioned within the cartridge receiver.

FIG. 9 is a diagram depicting the electrical connections of the cartridge receiver and the amplification assembly via the signal-in terminal and the signal-in port, wherein the input port is electrically connected to the pre-amplifier circuit.

FIG. 10 is a diagram depicting the electrical connections of the amplifier cartridge and the amplification assembly, wherein the input port is electrically connected to the speaker.

FIG. 11 is a diagram depicting the electrical connections with the power source, within the amplification assembly.

### DETAIL DESCRIPTIONS OF THE INVENTION

All illustrations of the drawings are for the purpose of describing selected versions of the present invention and are not intended to limit the scope of the present invention.

The present invention is a portable amplification unit that is integrated directly into the body of an electric instrument, thus eliminating external cables and devices. While the present invention is intended for use with electric guitars, the portable amplification unit can be used with any other electric instrument. In the preferred embodiment of the present invention, the portable amplification unit is designed to be retrofitted to an existing instrument; however, the portable amplification unit may be integrated into new instruments at the time of manufacture if so desired.

The portable amplification unit comprises an amplification assembly 7, an amplifier cartridge 2, a speaker 8, and a cartridge receiver 1. The cartridge receiver 1 is attached to the desired instrument and serves as a docking station for the amplifier cartridge 2. The amplification assembly 7 is positioned within the amplifier cartridge 2 and allows the user to readily manipulate the electrical signal of the electric instrument. Signal loss between where the electrical signal is generated and where the electrical signal is amplified is significantly reduced as a result of the amplification assembly 7 being closely wired to where the electronic signal is generated within the electric instrument. More specifically, the amplification assembly 7 is integrated with an electronics circuit of the electric instrument 5. The amplifier cartridge 2 is removably attached to the cartridge receiver 1 such that the amplifier cartridge 2 can be removed for maintenance or replaced. In the preferred embodiment of the present invention, the cartridge receiver 1 is mounted externally on the desired electric instrument; however, it is also possible for the cartridge receiver 1 to be mounted to the desired electric instrument internally. It is also possible for the amplifier cartridge 2, the amplification assembly 7, and the speaker 8 to be integrated directly into the electric instrument 5 at the time of manufacture.

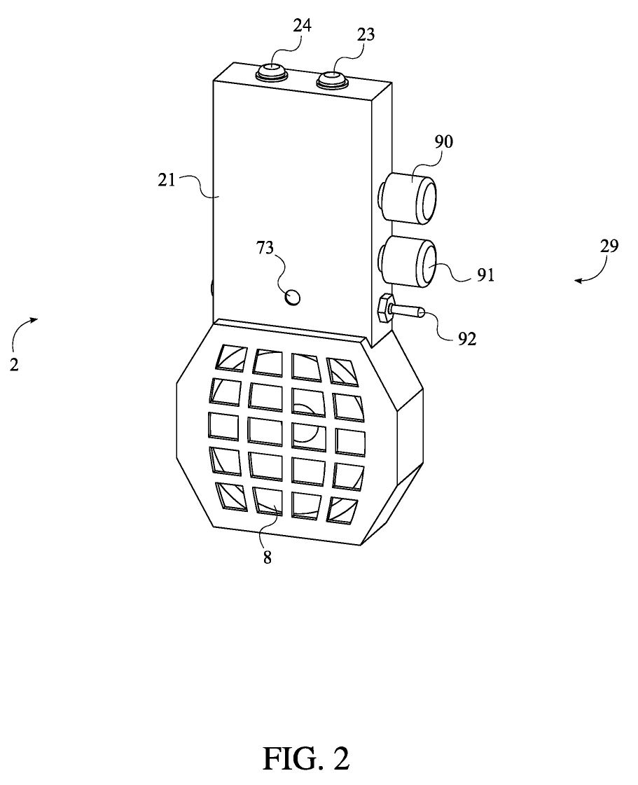

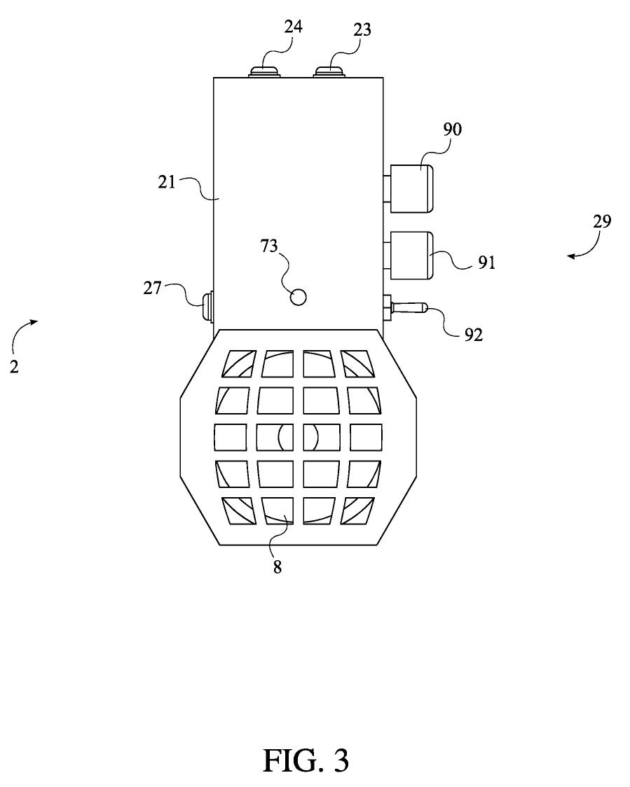

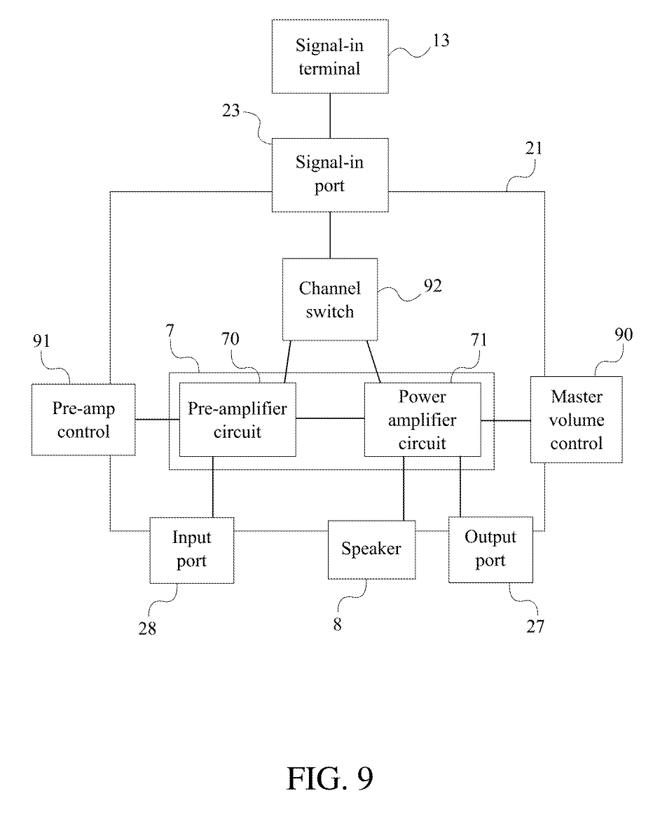

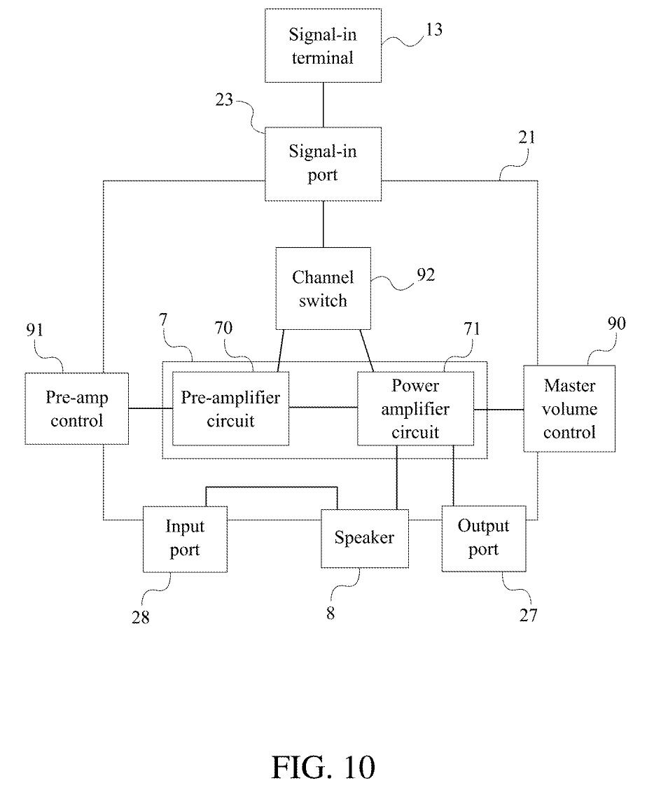

In reference to FIG. 2-3, the amplifier cartridge 2 comprises a cartridge casing 21, a signal-in port 23, a retention port 24, and an at least one amplifier control 29. The cartridge casing 21 is a generally thin-walled structure that provides a housing for the amplification assembly 7, as well as a mounting frame for the signal-in port 23, the retention port 24, and the at least one amplifier control 29. The signal-in port 23 and the retention port 24 are connected to the cartridge casing 21, wherein the signal-in port 23 and the retention port 24 are positioned through the top side of the cartridge casing 21. The amplification assembly 7 is substantially positioned within the cartridge casing 21 and provides the various electrical components and wiring required to amplify the electronic signal of the electric instrument. As such, the signal-in port 23 is electronically connected to the amplification assembly 7, wherein the amplifier cartridge 2 is electronically connected to the cartridge receiver 1 through the signal-in port 23, as depicted in FIG. 9-10. The retention port 24 is not electrically connected to the amplification assembly 7 and is simply used to retain the amplifier cartridge 2 within the cartridge receiver 1.

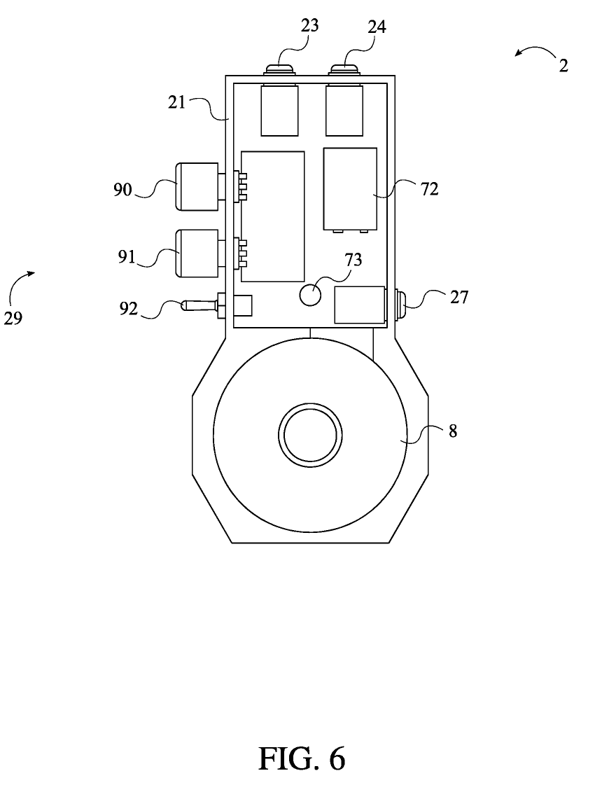

In reference to FIG. 6, the amplification assembly 7 comprises a power amplifier circuit 71, a pre-amplifier circuit 70, and a power source 72. The power amplifier circuit 71, the pre-amplifier circuit 70, and the power source 72 are positioned within the cartridge casing 21. The pre-amplifier circuit 70 and the power amplifier circuit 71 are electrically connected to each other in order to fully amplify the electrical signal of the electric instrument, such that the electrical signal can drive the speaker 8. The pre-amplifier circuit 70 provides an initial amplification stage, while the power amplifier circuit 71 provides a final amplification stage for producing the amplified signal to drive the speaker 8. As such, the pre-amplifier circuit 70 is electrically connected to the signal-in port 23 to receive an initial electrical signal, while the power amplifier circuit 71 is electrically connected to the speaker 8. Both the power amplifier circuit 71 and the pre-amplifier circuit 70 provide the electrical components necessary for amplifying the electrical signals received from the electric instrument, such as resistors, transistors, capacitors, and transducers.

The speaker 8 allows the present invention to produce sound directly from the amplifier cartridge 2. As such, the speaker 8 is positioned within the cartridge casing 21, and is electrically connected to the power amplifier circuit 71. In this way, the incoming electrical signal is amplified first by the pre-amplifier circuit 70 and then by the power amplifier circuit 71, such that the electrical signal can be used to drive the speaker 8. The speaker 8 is positioned adjacent to one or more openings in the cartridge casing 21, as shown in FIG. 2-3, such that the speaker 8 is able to project sound out of the cartridge casing 21.

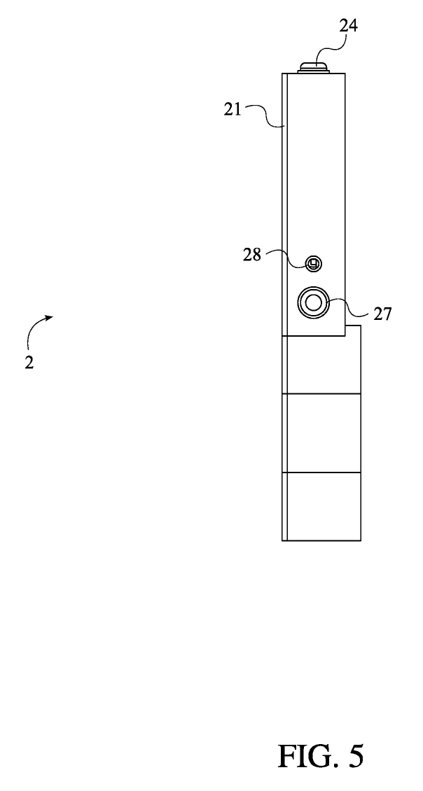

In reference to FIG. 5, the amplifier cartridge 2 may further comprise an output port 27 for directing the amplified signal to a device other than the speaker 8. Similar to the signal-in port 23, the output port 27 is connected to the cartridge casing 21, wherein the output port 27 is positioned through a side of the cartridge casing 21. The output port 27 and the second output port 27 are is electrically connected to the power amplifier circuit 71, wherein the amplified signal is directed from the power amplifier circuit 71 to the output port 27. In one embodiment, the output port 27 is a headphone output for directing the signal to headphones, wherein the speaker 8 is silenced when the headphone output is in use. In another embodiment, the output port 27 is a speaker output for directing the amplified signal to an external speaker, wherein the external speaker can be used standalone or in tandem with the speaker 8 of the portable amplification unit.

In some embodiments, the amplifier cartridge 2 may comprise more than one output port. For example, a first output port and a second output port for directing the amplified signal to different types of external devices. The more than one output port provides greater versatility, allowing for different connectors to be plugged into the amplifier cartridge 2. Furthermore, the more than one output port may allow the amplified signal to be directed to multiple external sources at the same time. For example, the amplified signal could be directed to a pair of headphones and a recording system simultaneously.

The amplifier cartridge 2 may also further comprise an input port 28 for connecting external devices to the speaker 8. For example, a digital music player can be connected to the speaker 8 through the input port 28, allowing the user to play the electric instrument along with the music played from the digital music player. The input port 28 is connected to the cartridge casing 21, wherein the input port 28 is positioned through a side of the cartridge casing 21. The input port 28 can be electrically connected directly to the speaker 8, as depicted in FIG. 10, or electrically connected to the speaker 8 through the pre-amplifier circuit 70 and the power amplifier circuit 71, as depicted in FIG. 9.

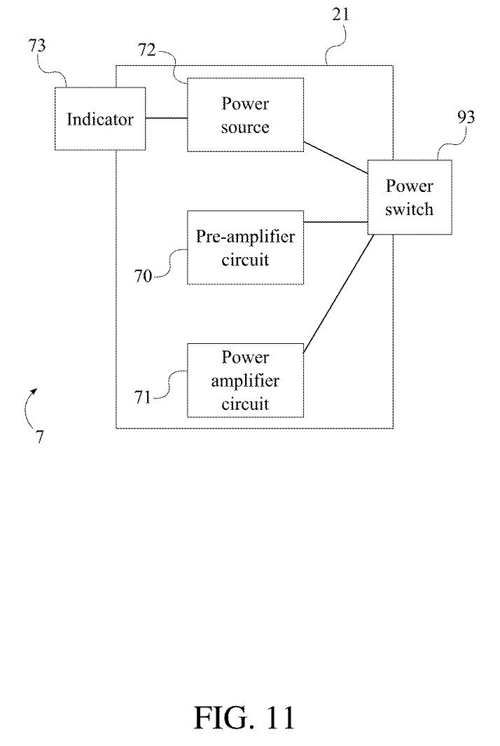

In reference to FIG. 11, the power amplifier circuit 71 and the pre-amplifier circuit 70 are electrically connected to the power source 72, such that the power source 72 supplies current to the electrical components of both the power amplifier circuit 71 and the pre-amplifier circuit 70. The power source 72 is ideally a battery, either rechargeable or non-rechargeable, and can use any known type of battery technology, such as lithium-ion technology, nickel-cadmium technology, etc. If the power source 72 is a rechargeable battery, then a charging port may also be integrated into the cartridge casing 21, such that the power source 72 does not need to be removed for recharging. If the power source 72 is a non-rechargeable battery, then an access panel may be integrated into the cartridge casing 21 in order to allow the power source 72 to be removed and replaced. If the power source 72 is not a battery, then the electric instrument 5 or the amplifier cartridge 2 may provide a charging port for attaching a power cord between the power source 72 and a power supply such as an outlet.

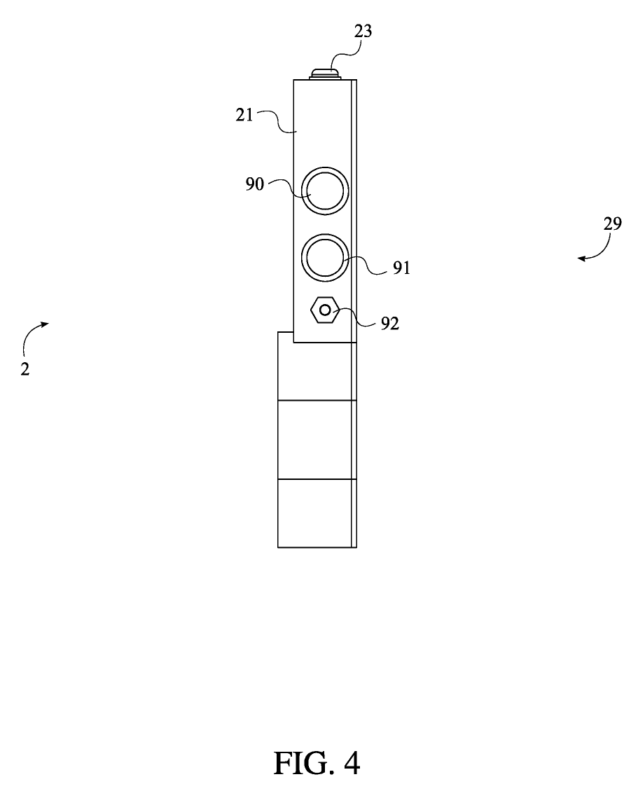

The at least one amplifier control 29 is connected to the cartridge casing 21, wherein the at least one amplifier control 29 is positioned externally on the cartridge casing 21, such that the at least one amplifier control 29 is readily accessible to the user, as shown in FIG. 3-4. In a minimalistic embodiment, the at least one amplifier control 29 comprises only a master volume control 90 used to adjust the volume of sound emitted from the speaker 8. As such, the master volume control 90 is electrically connected to the power amplifier circuit 71, and is rotatably connected to the cartridge casing 21 such that rotation of the master volume control 90 adjusts the volume output accordingly.

In another embodiment, the at least one amplifier control 29 comprises the master volume control 90 in addition to a pre-amp control 91, a tone control, and a channel switch 92. The master volume control 90, or clean control, is electrically connected to the power amplifier circuit 71, while the pre-amp control 91, or gain control, is electrically connected to the pre-amplifier circuit 70. Similar to the master volume control 90, the pre-amp control 91 is rotatably connected to the cartridge casing 21 such that rotation of the pre-amp control 91 adjusts the gain of the pre-amplifier circuit 70 accordingly. The pre-amp control 91 is integrated into a first signal path of the amplification assembly 7, wherein the electrical signal from the electric instrument is sent through the pre-amplifier circuit 70 and the power amplifier circuit 71. Meanwhile, a second signal path of the amplification assembly 7 bypasses the pre-amp control 91 and the pre-amplifier circuit 70, wherein the electrical signal goes directly to the power amplifier circuit 71. The channel switch 92 allows the user to toggle between the first signal path and the second signal path. The tone control can be electronically connected to the pre-amplifier circuit 70 or the power amplifier circuit 71 in order to further manipulate the sound of the electric instrument.

In other embodiments, the at least one amplifier control 29 further comprises an effects switch and an effects level control. The effects level control is electrically connected to a tone effects circuit 43 of the amplification assembly 7, wherein the tone effects circuit 43 is electrically connected to the pre-amplifier circuit 70 and the power amplifier circuit 71. The tone effects circuit 43 is utilized to apply a desired sound effect to the electronic signal, such as a delay effect, a phaser effect, a flanger effect, etc., while the effects level control allows the user to adjust the extent to which the effect is applied. The effects switch is electrically connected to the amplification assembly 7 such that the path of the electronic signal can be toggled through the tone effects circuit 43 by the user.

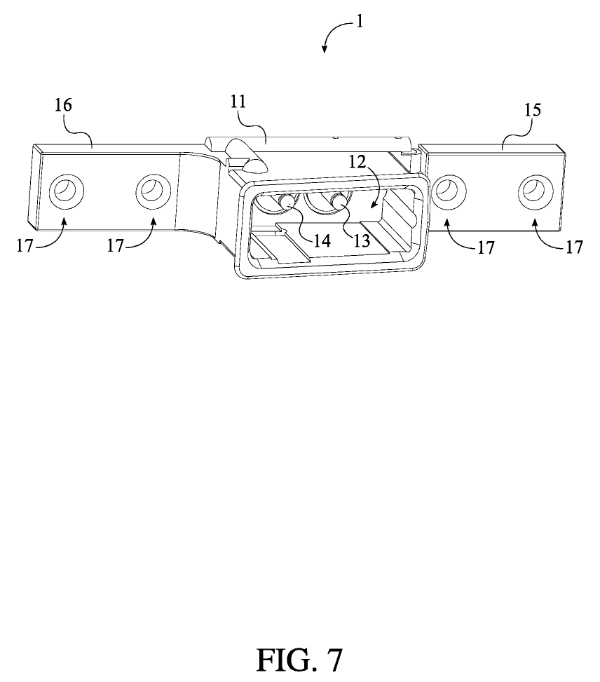

In reference to FIG. 7, the cartridge receiver 1 comprises a receiver body 11, a receiving volume 12, a signal-in terminal 13, a signal-out terminal 14, and a plurality of holes 17. The receiving body is the central structure of the cartridge receiver 1 and defines the general shape of the cartridge receiver 1. The receiving volume 12 is positioned into the receiver body 11 and is the empty space into which the amplifier cartridge 2 is positioned when the amplifier cartridge 2 is attached to the cartridge receiver 1. The signal-in terminal 13 and the signal-out terminal 14 are connected to the receiver body 11 and are positioned within the receiving volume 12. The cartridge receiver 1 is preferably mounted externally on the electric instrument 5; however, it is also possible for the cartridge receiver 1 to be mounted to the electric instrument 5 internally. The signal-in terminal 13 and the signal-out terminal 14 are electrically connected to the electronics circuit, and the amplifier cartridge 2 is electrically connected to the cartridge receiver 1 through the signal-in terminal 13.

The plurality of holes 17 provides a means of connection between the electric instrument and the cartridge receiver 1. The plurality of holes 17 traverses through the receiver body 11, wherein screws are inserted through each of the plurality of holes 17 and threaded into screw holes drilled into the electric instrument in order to connect the cartridge receiver 1 to the electric instrument. Alternatively, the screws can be threaded directly into the surface of the electric instrument. Additional holes are drilled through the electric instrument adjacent to the receiver body 11 in order to allow electrical wire to be connected to the signal-in terminal 13.

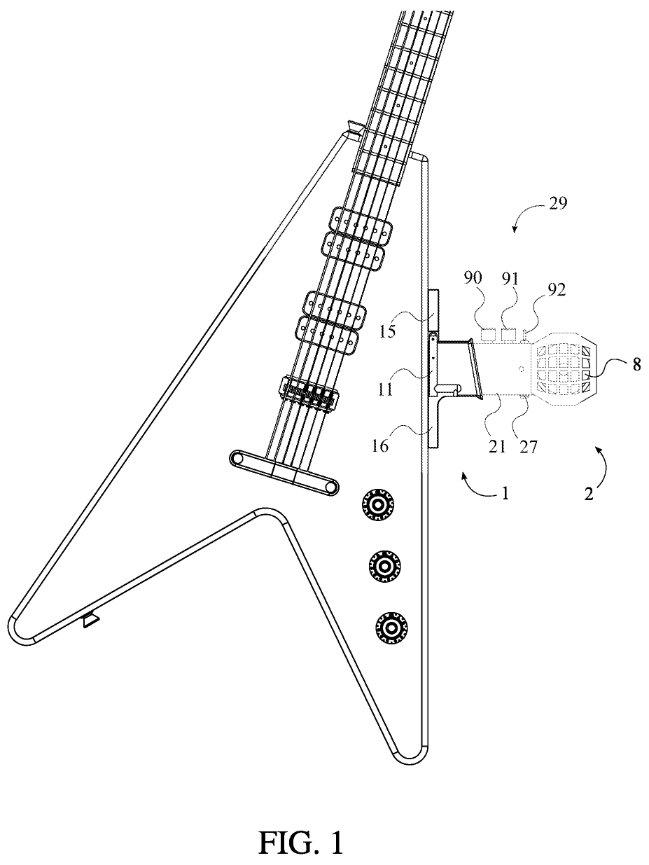

In some embodiments, the cartridge receiver 1 further comprises a first flange 15 and a second flange 16 that are adjacently connected to the receiver body 11, wherein the plurality of holes 17 traverses through both the first flange 15 and the second flange 16. The first flange 15 and the second flange 16 are positioned on the receiver body 11 opposite the receiving volume 12. In this way, the first flange 15, the second flange 16, and the top of the receiver body 11 rest flush against the surface of the electric instrument, while the receiving volume 12 is directed away from the electric instrument, such that the amplifier cartridge 2 can be attached to the cartridge receiver 1. The first flange 15 and the second flange 16 are positioned opposite each other across the receiver body 11 in order to securely hold the cartridge receiver 1 flush against the surface of the electric instrument, as shown in FIG. 1. It is also possible for the cartridge receiver 1 to be connected to the electric instrument in any other way, such as being internally positioned within the electric instrument.

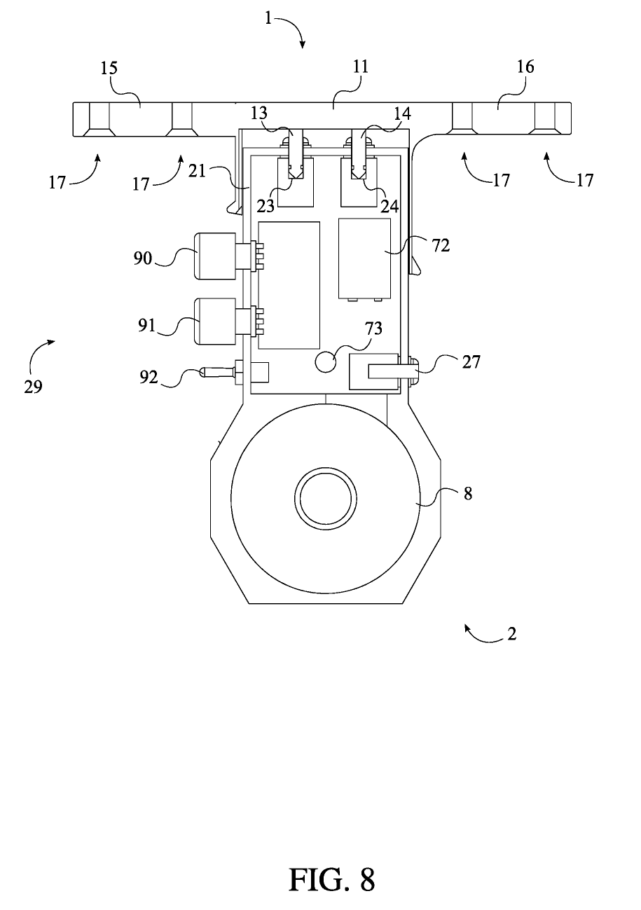

In reference to FIG. 8, when the amplifier cartridge 2 is attached to the cartridge receiver 1, the top end of the cartridge casing 21 is positioned into the receiving volume 12 of the cartridge receiver 1. As the cartridge casing 21 is inserted into the receiving volume 12, the signal-in terminal 13 of the cartridge receiver 1 engages the signal-in port 23, such that the signal-in terminal 13 is positioned into the signal-in port 23. When the signal-in terminal 13 is positioned into the signal-in port 23, the signal-in terminal 13 is electrically connected to the signal-in port 23, thus allowing the electronic signal of the electric instrument to be passed through the amplification assembly 7. Furthermore, the signal-out terminal 14 engages the retention port 24, such that the signal-out terminal 14 is positioned within the retention port 24. The signal-out terminal 14 and the retention port 24 are not electrically connected, however, the engagement of the signal-out terminal 14 and the retention port 24 secures the amplifier cartridge 2 within the cartridge receiver 1.

In the preferred embodiment of the present invention, the power source 72 automatically supplies current to the power amplifier circuit 71 and the pre-amplifier circuit 70 when the signal-in terminal 13 engages the signal-in port 23. Moreover, the amplification assembly 7 further comprises an indicator 73, such as a light emitting diode, that is integrated into the cartridge casing 21, as shown on the front of the cartridge casing 21 in FIG. 3. The indicator 73 is electrically connected to the power source 72 such that the indicator 73 is illuminated when the amplifier cartridge 2 engages the cartridge receiver 1, demonstrating that current is also supplied to the power amplifier circuit 71 and the pre-amplifier circuit 70. In other embodiments of the present invention, the amplification assembly 7 may further comprise a power switch 93 connected to the cartridge casing 21 for toggling the power source 72 on and off, wherein the power switch 93 is electrically connected in between the power source 72 and both of the pre-amplifier circuit 70 and the power amplifier circuit 71.

The amplification assembly 7 can be always active, wherein the electrical signal of the electric instrument 5 is automatically passed through the amplification assembly 7 when the amplifier cartridge 2 is inserted into the cartridge receiver 1; or active as needed through the use of a changeover switch 3. The changeover switch 3 can be connected to the electric instrument 5, the amplifier cartridge 2, or the cartridge receiver 1. The changeover switch 3 allows the user to direct the electronic signal produced by the electric instrument from a normal path through the electric instrument to a manipulated path through the amplification assembly 7. The normal path follows the circuit of the electric instrument, while the manipulated path passes through the pre-amplifier circuit 70 and the power amplifier circuit 71. As such, the changeover switch 3 is electronically connected to the signal-in terminal 13 in order to operatively couple the changeover switch 3 to the amplification assembly 7.

In the preferred embodiment, the changeover switch 3 is a push-on/push-off style switch, wherein the changeover switch 3 is used to direct the electronic signal between the normal path and the manipulated path. When the changeover switch 3 is in the off position, the electronic signal is directed along the normal path through the circuit of the electric instrument and is not manipulated. When the changeover switch 3 is in the on position, the electronic signal is directed along the manipulated path through the amplifier assembly.

The changeover switch 3 is connected to the electric instrument such that it is accessible to the user. Ideally, the changeover switch 3 is used as a replacement to an existing control of the electric instrument. For example, if the portable amplification unit is used in conjunction with an electric guitar, then a tone control of the electric guitar can be removed and replaced with the changeover switch 3, thus minimizing any alterations to the electric instrument (i.e. drilling additional holes into the instrument body). Of course, it is also possible for the changeover switch 3 to be mounted to any other accessible region of the electric instrument.

When the amplifier cartridge 2, the amplification assembly 7, and the speaker 8 are manufactured directly into the electric instrument 5, the amplifier cartridge 2 is positioned within the electric instrument 5. Meanwhile, the speaker 8 is mounted into the electric instrument 5. The electronics circuit of the electric instrument 5 is electrically connected to the amplification assembly 7 through the signal-in port 23, such that the electrical signal generated through the electronics circuit can be passed through the pre-amplifier circuit 70 and the power amplifier circuit 71 in order to amplify the electrical signal. The amplification assembly 7 can be always active, wherein the amplification assembly 7 is integrated into the normal electrical path of the electronics circuit; or active as needed through the use of the changeover switch 3, wherein the amplification assembly 7 is isolated from the normal electrical path of the electronics circuit.

The present invention may also include a movement actuated tone effects unit 4 in embodiments which utilize the tone effects circuit 43. The movement actuated tone effects unit 4 allows a user to apply sound effects to the electric instrument 5 through movement of the electric instrument 5, as opposed to through the manipulation of controls, such as potentiometers, switches, etc. Thus, the movement actuated tone effects unit 4 provides a much more dynamic control over the sound of the electric instrument 5. The movement actuated tone effects unit 4 comprises a motion sensor unit 49 and a processor 42, wherein the motion sensor unit 49 and the processor 42 are electrically connected to the power source 72.

The motion sensor unit 49 is used to determine the directional motion of the electric instrument 5. To do so, the motion sensor unit 49 measures the rate of change of the movement of the electric instrument 5 in relation to a set of reference axes (i.e. a x-axis, y-axis, and z-axis). The motion sensor unit can include an accelerometer 40, or a gyroscope 41, or a combination thereof. The accelerometer 40 measures the proper acceleration, or the linear acceleration, of the electric instrument 5, and can be either a single-axis model or a multi-axis model, depending on the application of the accelerometer 40. The accelerometer 40 is not limited in the components that can be used to convert the mechanical motion of the accelerometer 40 into an electrical signal. For example, the accelerometer 40 may comprise piezoelectric, piezoresistive, or capacitive components in accordance with the accelerometer 40 being of the piezoelectric, piezoresistive, or capacitive variety respectively. It is also possible for the present invention to include more than one accelerometer. The gyroscope 41 is used to determine the angular rotational velocity of the electric instrument 5, or the rotation/twist of the electric instrument 5, about the set of reference axes. Specifically, the gyroscope 41 will measure the roll, pitch, and yaw of the electric instrument 5. Similar to the linear motion detected by the accelerometer 40, each of the roll, pitch, and yaw motions detected by the gyroscope 41 is converted into an electrical signal. In the preferred embodiment of the present invention, the motion sensor unit 49 is a three axis gyroscope accelerometer sensor module.

When the motion sensor unit 49 is set in motion, the mechanical motion is converted into electrical signals, which are sent to the processor 42. As such, the motion sensor unit 49 is electronically connected to the processor 42. The processor 42 is any electrical device that is capable of receiving input signals and producing output signals or operations based on pre-defined instructions stored on the processor 42 or a separate memory device, such as a central processing unit, microprocessor, application-specific processor, etc. In the given application, the input signals to the processor 42 are the electrical signals that are output and transmitted by the motion sensor unit 49. If the separate memory device is used, then the separate memory device is electronically connected to the processor 42.

After receiving and processing an input signal from the motion sensor unit 49, the processor 42 sends an output signal to the tone effects circuit 43 in order to manipulate the electrical signal of the electric instrument 5 with the desired tone effect. As such, the tone effects circuit 43 is also electronically connected to the processor 42. The tone effects circuit 43 provides the various electrical components and wiring required to manipulate the electrical signal of the electric instrument 5 in the desired manner. For example, if the effects assembly is to embody a traditional wah-wah pedal, then the effects assembly would comprise electrical components for a tone-filter, such as a potentiometer, resistors, transistors, capacitors, and inductors. The effects assembly may be configured to produce one tone effect or multiple tone effects. Potentiometers used in the tone effects circuit 43, to either produce effects or control the extent of an effect, can be either a digital potentiometer controlled directly by the processor 42, or an analog potentiometer controlled indirectly by the processor 42 through a two-way motor or similar device.

The present invention may further comprise a calibration button 6. The calibration button 6 is electronically connected to the processor 42 and is used to calibrate the set of reference axes for the motion sensor unit 49. In this way, the electric instrument 5 does not need to be held in the exact same position each time the electric instrument 5 is played. Rather, the user selects an initial playing position for the electric instrument 5 and then actuates the calibration button 6 in order to calibrate the set of reference axes in relation to the initial position of the electric instrument 5.

By utilizing the motion sensor unit 49 to dictate the implementation of the tone effects circuit 43, a whole new playing style is opened to the user. Instead of actuating tone effects through separate stomp boxes, the user can simply motion the electric instrument 5 in the appropriate direction in order to achieve the desired effect. For example, if the tone effects circuit 43 is made to embody a wah-wah pedal, then the wah-wah effect would be produced by moving the electric instrument 5 back and forth along a specific axis from the set of reference axes; as opposed to manipulating a rocking pedal by the user's foot.

If the movement actuated tone effects unit 4 is used to only control the implementation of an effect and not the extent to which the effect is applied, then the present invention may further comprise an at least one tone effects control 25. For example, a distortion effect can be activated and deactivated by pitching the electric instrument 5 about a given axis from the set of reference axes, while the extent to which the electrical signal of the electric instrument 5 is distorted is determined by adjusting the at least one tone effects control 25. As such, the at least one tone effects control 25 is electrically connected to the tone effects circuit 43. The duration for which the effect is applied can also be predetermined through the use of a timer, which may be integrated into the processor 42 or may be independent of the processor 42 yet electronically controlled by the processor 42. The at least one tone effects control 25 can be a simple switch, potentiometer and knob combination, etc. that is electrically connected to the tone effects circuit 43. Alternatively, the at least one tone effects control 25 can be a power switch used to control the current supplied by the power source 72.

Similar to the changeover switch 3, if the calibration button 6 is utilized, then the calibration button 6 can be integrated into the electric instrument 5 in place of a pre-existing instrument control. Alternatively, the calibration button 6 can be integrated into the amplifier cartridge 2 or the cartridge receiver 1 in the retro fit embodiment. Additionally, the at least one tone effects control 25 can be integrated into the electric instrument 5 in the same manner, or integrated into the amplifier cartridge 2 or the cartridge receiver 1 in the retro fit embodiment.

In some embodiments of the present invention, the movement actuated tone effects unit 4 further comprises a signal converter 45 and a transmitter 47. The signal converter 45 alters the electrical signal of the electric instrument 5 from an analog signal to a digital signal, such that the transmitter 47 is able to transmit the digital signal to an electronic device synchronized with the transmitter 47. The electrical signal of the electric instrument 5 is first manipulated by the tone effects circuit 43, then converted to the digital signal by the signal converter 45, and finally transmitted to the synchronized electronic device by the transmitter 47. As such, the signal converter 45 is electrically connected to the tone effects circuit 43 in order to receive the electrical signal and is electronically connected to the transmitter 47 in order to relay the digital signal. The power source 72 is electrically connected to the signal converter 45 and the transmitter 47, and thus supplies current to both the signal converter 45 and the transmitter 47. Once the digital signal is transmitted to the electronic device, the digital signal can then be manipulated by the synchronized electronic device. As the electrical signal of the electric instrument 5 is converted to the digital signal and transmitted to the electronic device, the electrical signal does not need to re-enter the normal path of the electric instrument 5.

In yet other embodiments of the present invention, the movement actuated tone effects unit 4 further comprises a signal converter 45 and a device terminal 46, while either the electric instrument 5 or the amplifier cartridge 2 further comprises a device dock 26. The device dock 26 is a cavity positioned into the electric instrument 5, or the cartridge casing 21, that allows an electronic device, such as a mobile phone, to be attached to the electric instrument 5, or the amplifier cartridge 2. The device terminal 46 is connected to the electric instrument 5 or the cartridge casing 21, and is positioned into the device dock 26. The device terminal 46 provides an electronic connection, as well as an electrical connection, between the tone effects circuit 43 and the electronic device. As such, the device terminal 46 is electronically connected to the signal converter 45, while the signal converter 45 is electrically connected to the tone effects circuit 43. When the electronic device is positioned within the device dock 26 and attached to the device terminal 46, the incoming electrical signal is directed through the signal converter 45 and converted to the digital signal, wherein the digital signal is then directed to the electronic device through the device terminal 46. As the electrical signal of the electric instrument 5 is converted to the digital signal and then transmitted to the electronic device, the electrical signal does not need to re-enter the normal path of the electric instrument 5. Additionally, as the device terminal 46 is electrically connected to the tone effects circuit 43, current can be supplied to the tone effects circuit 43 from the electronic device, such that the power source 72 is supplemented or not needed. Additionally, the power source 72 can be used to charge or provide current to the electronic device. The electronic device can be used to apply additional sound effects to the electrical signal after the electrical signal has been amplified and converted, transmit the digital signal to another device, record the digital signal, etc.

The following provides additional examples of use of the tone effects circuit 43 in conjunction with the motion sensor unit 49. In a first example, the tone effects circuit 43 embodies a delay or echo effect circuit. The delay time can be controlled by pitching the electric instrument 5 about an x-axis, while the repeats can be controlled by pitching the electric instrument 5 about a y-axis, wherein the x-axis and the y-axis are from the set of reference axes. In a second example, the tone effects circuit 43 embodies a pitch effects circuit, wherein pitching the electric instrument 5 about the x-axis or y-axis changes the pitch of the note being played. In a third example, the tone effects circuit 43 embodies both the volume and tone circuits of an electrical guitar, such that an electric guitar does not need any external control knobs. The volume and tone settings are instead adjusted by pitching the electric guitar about the set of reference axes.

Although the invention has been explained in relation to its preferred embodiment, it is to be understood that many other possible modifications and variations can be made without departing from the spirit and scope of the invention as hereinafter claimed.

What is claimed is:

1. A portable amplification unit comprises:
an amplifier cartridge;
an amplification assembly;
a speaker;
the amplifier cartridge comprising a cartridge casing and a signal-in port;
the amplification assembly comprising a power amplifier circuit, a pre-amplifier circuit, and a power source;
the signal-in port being positioned through the cartridge casing;
the signal-in port being connected to the cartridge casing;
the power amplifier circuit, the pre-amplifier circuit, and the power source being positioned within the cartridge casing;
the pre-amplifier circuit being electrically connected to the power source, the power amplifier circuit, and the signal-in port;
the power amplifier circuit being electrically connected to the power source and the speaker; and
the speaker being mounted into the cartridge casing.

2. The portable amplification unit as claimed in claim 1 comprises:
the amplifier cartridge further comprising a retention port;
the retention port being positioned through the cartridge casing;
the retention port being connected to the cartridge casing; and
the retention port being positioned adjacent to the signal-in port.

3. The portable amplification unit as claimed in claim 1 comprises:
the amplifier cartridge further comprising an output port;
the output port being positioned through the cartridge casing;
the output port being connected to the cartridge casing; and
the power amplifier being electrically connected to the output port.

4. The portable amplification unit as claimed in claim 1 comprises:
the amplifier cartridge further comprising an input port;
the input port being positioned through the cartridge casing; and
the input port being connected to the cartridge casing.

5. The portable amplification unit as claimed in claim 4 comprises:
the input port being electrically connected to the speaker.

6. The portable amplification unit as claimed in claim 4 comprises:
the input port being electrically connected to the pre-amplifier circuit.

7. The portable amplification unit as claimed in claim 1 comprises:
the amplifier cartridge further comprising an at least one amplifier control;
the at least one amplifier control being externally positioned on the cartridge casing; and
the at least one amplifier control being electrically connected to the amplification assembly.

8. The portable amplification unit as claimed in claim 7 comprises:
the at least one amplifier control comprising a master volume control;
the master volume control being electrically connected to the power amplifier circuit; and
the master volume control being rotatably connected to the cartridge casing.

9. The portable amplification unit as claimed in claim 7 comprises:
the at least one amplifier control comprising a pre-amp control;
the pre-amp control being electrically connected to the pre-amplifier circuit;
the pre-amp control being rotatably connected to the cartridge casing.

10. The portable amplification unit as claimed in claim 7 comprises:
the at least one amplifier control comprising a channel switch; and
the channel switch being electrically connected in between the signal-in port and both of the pre-amplifier circuit and the power amplifier circuit.

11. The portable amplification unit as claimed in claim 7 comprises:
the at least one amplifier control comprising a power switch; and
the power switch being electrically connected in between the power source and both of the pre-amplifier circuit and the power amplifier circuit.

12. The portable amplification unit as claimed in claim 1 comprises:
a cartridge receiver;
the cartridge receiver comprising a receiver body and a signal-in terminal;
the signal-in terminal being connected to the receiver body;
the amplifier cartridge being attached to the cartridge receiver;
the signal-in terminal being positioned into the signal-in port; and
the signal-in terminal being electrically connected to the signal-in port.

13. The portable amplification unit as claimed in claim 12 comprises:
the amplifier cartridge further comprising a retention port;
the cartridge receiver further comprising a signal-out terminal;
the signal-out terminal being connected to the receiver body; and
the signal-out terminal being positioned into the retention port.

14. The portable amplification unit as claimed in claim 1 comprises:
a cartridge receiver;
the cartridge receiver comprising a receiver body, a receiving volume, and a signal-in terminal;
the receiving volume being positioned into the receiver body;
the signal-in terminal being positioned within the receiving volume; and
the cartridge casing being positioned into the receiving volume.

15. The portable amplification unit as claimed in claim 14 comprises:
the cartridge receiver further comprising a signal-out terminal;
the signal-out terminal being positioned adjacent to the signal-in terminal; and
the signal-out terminal being positioned within the receiving volume.

16. The portable amplification unit as claimed in claim 1 comprises:
a cartridge receiver;
the cartridge receiver comprising a receiver body, a first flange, a second flange, and a plurality of holes;
the first flange and the second flange being adjacently connected to the receiver body;
the first flange and the second flange being positioned opposite each other across the receiver body;
the plurality of holes traversing through both the first flange and the second flange; and
the amplifier cartridge being attached to the cartridge receiver.

17. The portable amplification unit as claimed in claim 1 comprises:
the amplification assembly further comprising an indicator; and
the indicator being electrically connected to the power source.
